(19) United States
(12) Patent Application Publication
(10) Pub. No.: US 2025/0048755 A1
(43) Pub. Date: Feb. 6, 2025

(54) SENSOR FOR SENSING VISIBLE AND INFRARED IMAGES, AND METHOD FOR PRODUCING SUCH A SENSOR

(71) Applicant: Commissariat à I'Énergie Atomique et aux Énergies Alternatives, Paris (FR)

(72) Inventors: Sébastien Becker, Grenoble (FR); Abdelkader Aliane, Grenoble (FR); Jérôme Vaillant, Grenoble (FR)

(73) Assignee: Commissariat à I'Énergie Atomique et aux Énergies Alternatives, Paris (FR)

(21) Appl. No.: 18/717,937

(22) PCT Filed: Dec. 1, 2022
(86) PCT No.: PCT/EP2022/083961

§ 371 Date: Jun. 7, 2024

(30) Foreign Application Priority Data
Dec. 14, 2021 (FR) FR2113457

(51) Int. Cl. H01L 27/146

(52) U.S. Cl. CPC H01L 27/1465; H01L 27/14629; H01L 27/1463; H01L 27/14645; H01L 27/1469; H01L 27/14692

(57) ABSTRACT

A visible and infrared image sensor, including: a first active layer for detecting visible radiation, in which a plurality of visible detection pixels are defined; and superimposed on the first active layer, a second active layer for detecting infrared radiation, in which a plurality of infrared detection pixels are defined, wherein the second active layer defines a vertical resonant cavity for said infrared radiation, the sensor further including, on the side of the face of the second active layer opposite the first active layer, a control integrated circuit superimposed on the first and second active layers.

The present application is based on, and claims the priority of, French patent application FR2113457 filed on Dec. 16, 2022 and entitled “Capteur d'images visibles et infrarouges et procédé de fabrication d'un tel capteur”, which is considered an integral part of the present description to the extent provided by law.

### TECHNICAL FIELD

The present application relates to the field of image acquisition devices, and more particularly to image acquisition devices adapted to acquire, simultaneously or successively, a visible image and an infrared image of a scene, for example for applications requiring the acquisition, simultaneously or successively, of a visible two-dimensional (2D) image of a scene and a depth map of this same scene.

### BACKGROUND ART

Patent applications US2019191067 and US2021305206, previously filed by the applicant, describe examples of devices including a visible image sensor and an infrared image sensor superimposed on each other. Furthermore, patent application FR2105161 filed on May 18, 2021 and entitled “Procédé de fabrication d'un dispositif optoélectronique” describes, in relation to its FIGS. 10A to 10D, an example of a method for manufacturing a device including a visible detector and an infrared detector superimposed.

It would be desirable to improve at least in part some aspects of known visible and infrared image sensors, as well as known methods for producing such sensors.

### SUMMARY OF INVENTION

One embodiment provides a visible and infrared image sensor, comprising:
a first active layer for detecting visible radiation, in which a plurality of visible detection pixels are defined; and
superimposed on the first active layer, a second active layer for detecting infrared radiation, in which a plurality of infrared detection pixels are defined,
wherein the second active layer defines a vertical resonant cavity for said infrared radiation,
the sensor further comprising, on the side of the face of the second active layer opposite the first active layer, a control integrated circuit superimposed on the first and second active layers.

According to one embodiment, the first active layer and the second active layer are separated by an interface layer.

According to one embodiment, the interface layer has a thickness of between 10 and 800 nm.

According to one embodiment, the interface layer is non-metallic.

According to one embodiment, the interface layer is made of silicon oxide.

According to one embodiment, the interface layer comprises alternating first regions made of a dielectric material and second regions made of a semiconductor or metallic material.

According to one embodiment, the first active layer is made of silicon.

According to one embodiment, the second active layer is made of an inorganic semiconductor material.

According to one embodiment, the second active layer is made of germanium or silicon.

According to one embodiment, the sensor comprises a reflective layer, for example made of a doped semiconductor material, on the side of the face of the second active layer opposite the first active layer.

According to one embodiment, the infrared radiation is radiation with a wavelength between 900 nm and 2 μm.

Another embodiment provides a method for manufacturing a visible and infrared image sensor, comprising the following steps:
a) providing a first active layer for detecting visible radiation, in which a plurality of visible detection pixels are defined;
b) attaching a second active layer for detecting infrared radiation to the first active layer by direct bonding; and
c) defining a plurality of infrared detection pixels in the second active layer, wherein the second active layer defines a vertical resonant cavity for said infrared radiation,
the method further comprising, after step c), a step of transferring and attaching a silicon layer to the second active layer by direct bonding, and then forming MOS transistors in said silicon layer.

### BRIEF DESCRIPTION OF DRAWINGS

The foregoing features and advantages, as well as others, will be described in detail in the following description of specific embodiments given by way of illustration and not limitation with reference to the accompanying drawings, in which:

FIG. 1A;

FIG. 1B;

FIG. 1C;

FIG. 1D;

FIG. 1E;

FIG. 1F;

FIG. 1G;

FIG. 1H;

FIG. 1I;

FIG. 1J;

FIG. 1K;

FIGS. 1A to 1K are cross-sectional views illustrating steps of an example method for manufacturing a visible and infrared image sensor;

FIG. 2 is a diagram illustrating the evolution of the reflection of infrared radiation as a function of the thickness of an interface layer in an example sensor of the type produced by the method shown in FIGS. 1A to 1K;

FIG. 3 is a diagram illustrating the evolution of the reflection of infrared radiation as a function of the thickness of an interface layer in another example of a sensor of the type produced by the method shown in FIGS. 1A to 1K; and

FIG. 4 is a cross-sectional view illustrating a variant embodiment of a visible and infrared image sensor.

### DESCRIPTION OF EMBODIMENTS

Like features have been designated by like references in the various figures. In particular, the structural and/or functional features that are common among the various embodiments may have the same references and may dispose identical structural, dimensional and material properties.

For the sake of clarity, only the operations and elements that are useful for an understanding of the embodiments described herein have been illustrated and described in detail. In particular, the construction of the photodiodes and the control circuits for the visible and infrared detection pixels have not been described in detail, as the construction of these elements is within the capabilities of those skilled in the art on the basis of the indications in the present description.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, unless indicated otherwise, when reference is made to absolute positional qualifiers, such as the terms “front”, “back”, “top”, “bottom”, “left”, “right”, etc., or to relative positional qualifiers, such as the terms “above”, “below”, “higher”, “lower”, etc., or to qualifiers of orientation, such as “horizontal”, “vertical”, etc., reference is made to the orientation shown in the figures.

Unless specified otherwise, the expressions “around”, “approximately”, “substantially” and “in the order of” signify within 10%, and preferably within 5%.

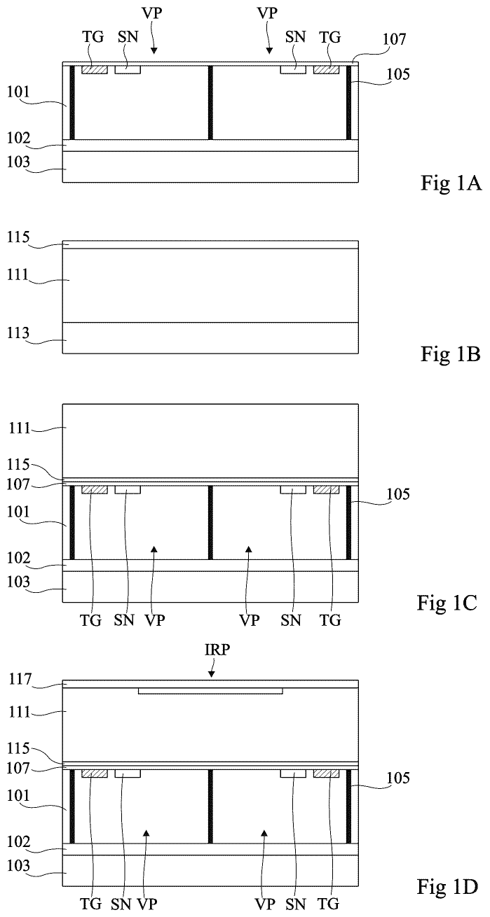

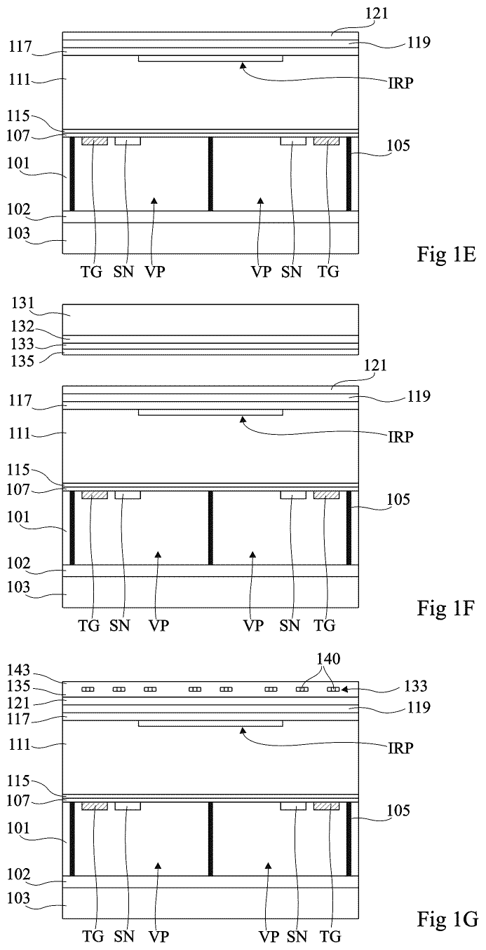

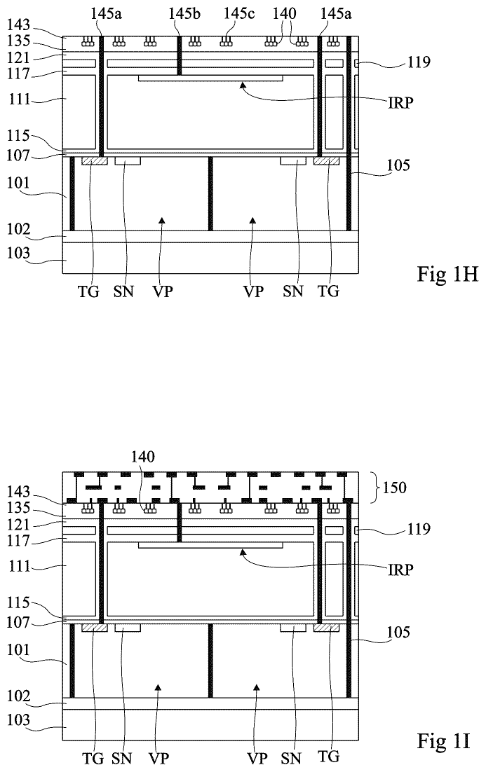

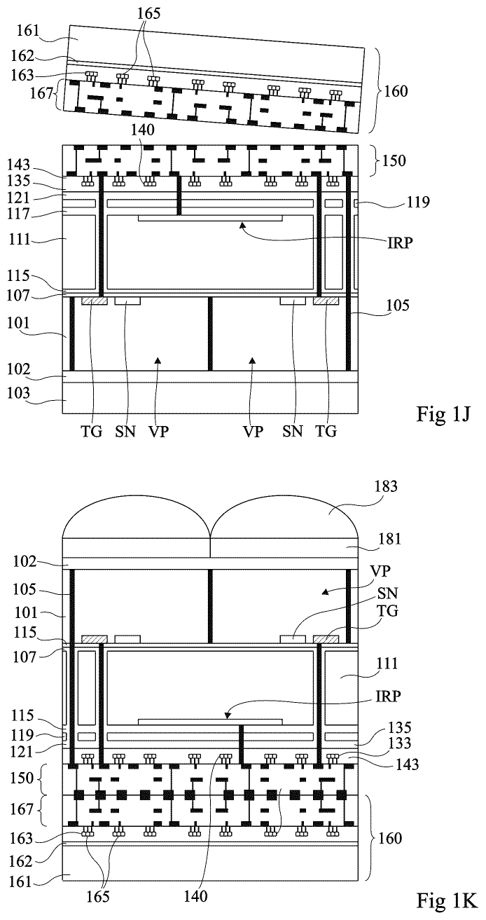

FIGS. 1A to 1K are cross-sectional views illustrating steps in an example method for manufacturing a visible and infrared image sensor.

FIG. 1A illustrates very schematically a first structure including an active visible detection layer 101, in which are defined a plurality of pixels VP for detecting visible radiation, for example arranged in a matrix pattern. The layer 101 is made of a semiconductor material, such as monocrystalline silicon. Layer 101 is, for example, the top semiconductor layer of a stack of the SOI (Silicon On Insulator) SOI type. In this example, the SOI stack comprises an electrically insulating layer 102, e.g. made of silicon oxide being in contact, via its top face, with the bottom face of layer 101, and a support layer 103, e.g. made of silicon being in contact, via its top side, with the bottom face of insulating layer 102. The thickness of the active layer 101 is, for example, between 2 and 10 μm, for example of the order of 4 μm.

Each pixel VP comprises an active part formed in and on the active layer 101. The active part comprises, for example, a photodiode (not detailed in the figure) and a sense node SN formed on the top face side of the layer 101. For example, the active part of each pixel VP further comprises a vertical or planar transfer gate TG, enabling the transfer of photo-generated electrical charges from the photodiode to the sense node SN to be activated. The active part of each pixel VP may optionally comprise one or more additional transistors, not detailed. The various elements making up the active part of each pixel VP will not be detailed further, as the embodiments described are compatible with all or most known photo-sensing pixel structures, for example with one or more transistors.

In this example, the active parts of the pixels VP are separated laterally from each other by insulating trenches or walls 105 extending vertically through the active layer 101, for example over the entire thickness of the layer 101. The trenches 105 are capacitive insulating trenches, for example of the CDTI (Capacitive Deep Trench Isolation) type, each comprising a core or central wall made of an electrically conductive material, for example doped polycrystalline silicon, and a lateral coating made of an electrically insulating material, for example silicon oxide. However, the embodiments described are not limited to this particular case. For example, the trenches 105 are insulating trenches completely filled with a dielectric material, such as silicon oxide, e.g. DTI trenches (Deep Trench Isolation). Insulating trenches 105 are formed, for example, from the top face of the active layer 101. The active parts of the pixels VP, for example, are all identical, within manufacturing dispersions.

In the example shown, the active layer 101 is coated with a passivation layer 107 of an electrically insulating material, e.g. silicon oxide. The layer 107 extends, for example, continuously over the entire surface of the structure. For example, the layer 107 is in contact with the top face of active layer 101, via its bottom face.

FIG. 1B illustrates a second structure including an active infrared detection layer 111. In this example, layer 111 is arranged on and in contact with the top face of a support substrate 113.

The active layer 111 comprises a material absorbing infrared radiation intended to be detected by the sensor, for example radiation emitted by an infrared source of an acquisition system comprising the visible and infrared image sensor, for example radiation with a wavelength of between 900 nm and 2 μm, for example radiation with a wavelength of the order of 940 nm, or radiation with a wavelength of the order of 1.4 μm.

For example, the active layer 111 is made of germanium. The active layer 111 is for example epitaxially formed on, and in contact with, the top face of the support substrate 113. For example, substrate 113 is made of silicon. In this example, active layer 111 is a single layer of an inorganic semiconductor material. Alternatively, depending on the type of infrared detector required, layer 111 can be formed of a stack of several semiconductor layers with different doping levels and/or types.

In the example shown, the active layer 111 is coated with a passivation layer 115 of an electrically insulating material, for example the same material as the layer 107 (FIG. 1A), e.g. silicon oxide. Layer 115 extends continuously over the entire surface of the structure. Layer 115 is in contact, for example, with the top face of active layer 111 via its bottom face.

FIG. 1C illustrates the structure obtained at the end of a step of transferring and attaching the structure shown in FIG. 1B to the structure shown in FIG. 1A, then removing substrate 113. In this example, the structure of FIG. 1B is attached by whole plate direct bonding (also known as molecular bonding) of the bottom face (in the orientation shown in FIG. 1C, corresponding to the top face in the orientation shown in FIG. 1B) of the dielectric layer 115 to the top face (in the orientation shown in FIG. 1C, corresponding to the top face in the orientation shown in FIG. 1A) of the layer 107.

The substrate 113 is then removed so as to expose the top face (in the orientation shown in FIG. 1C) of the active infrared detection layer 111. At this stage, the active layer 111 extends continuously and with a substantially uniform thickness over the entire top surface of the underlying visible detection structure.

FIG. 1D illustrates the structure obtained after steps of forming infrared detectors defining respectively a plurality of infrared detection pixels IRP in the active layer 111, for example arranged in a matrix pattern. Forming the infrared detectors of the pixels IRP comprises, for example, one or more implantation steps on the top face side of layer 111. The infrared detectors of the device can be of different types, depending on the type of infrared detection required. By way of example, the infrared detectors are conventional photodiodes for measuring infrared flux. Alternatively, the infrared detectors are current-assisted photonic demodulators (CAPDs), for example of the type described in the article entitled “Design and Characterization of Current-Assisted Photonic Demodulators in 0.18-μm CMOS Technology” by Gian-Franco Dalla Betta et al., to measure a modulation of an infrared signal in order to provide depth information, or any other type of photodetector. The various elements constituting infrared detection pixels IRP will not be described in more detail, as the embodiments described are compatible with all or most known infrared detection pixel structures. The infrared detection pixels IRP are, for example, aligned with the underlying visible detection pixels VP. The pitch (center-to-center distance between two neighboring pixels) of the pixel IRP matrix can be different from the pitch of the pixel VP matrix. By way of example, the pitch of the pixel IRP matrix is twice as large (in both row and column directions) as the pitch of the pixel VP matrix.

In this example, the top face of the active layer 111 is coated with a passivation layer 117, for example made of an electrically insulating material, e.g. silicon oxide. The layer 117 is in contact, via its bottom face, with the top face of active layer 111. Alternatively, the passivation layer 117 comprises a stack, not detailed in the figure, comprising a silicon layer, not shown, for example a few nanometers thick, e.g. 1 to 25 nm thick, in contact, via its bottom face, with the top face side of the active layer 111, and a dielectric layer, e.g. made of silicon oxide, being in contact, via its bottom face, with the top face of the silicon layer. By way of example, layer 117 extends continuously over the entire top surface of the structure. Layer 117 is deposited, for example, prior to the one or more steps of implanting dopant elements to form the infrared detectors of the pixels IRP.

FIG. 1E illustrates the structure obtained after a step of depositing a layer 119 forming a reflector for the infrared radiation to be detected by the sensor, on the top face of the passivation layer 117. The reflective layer 119 extends, for example, continuously and with a substantially uniform thickness over the entire top surface of the structure. The layer 119 is in contact, via its bottom face, with the top surface of passivation layer 117. Reflective layer 119 is preferably non-metal. By way of example, reflective layer 119 is made of a highly doped semiconductor material, e.g. silicon, with a concentration of N- or P-type doping elements greater than 10²⁰ atoms/cm³ and a thickness of the order of 400 nm or more.

In this example, a layer made of an electrically insulating material 121, e.g. silicon oxide, is further deposited on the top face of the reflective layer 119. For example, the layer 121 is in contact, via its bottom face, with the top face side of the layer 119. Layer 121 extends, for example, continuously and with a substantially uniform thickness over the entire top surface of the structure.

FIG. 1F illustrates a step for attaching an SOI structure by direct bonding to the top face of the structure shown in FIG. 1E. The SOI structure comprises, in order, a support substrate 131, for example made of silicon, an electrically insulating layer 132, for example made of silicon oxide, on and in contact with, one face of the support substrate 131, and an active semiconductor layer 133, for example made of monocrystalline silicon, on, and in contact with, the face of the insulating layer 132 opposite the support substrate, i.e. its bottom face in the orientation shown in FIG. 1F. In the example shown, the SOI structure further comprises a layer 135 made of an electrically insulating material, for example the same material as layer 121, coating the bottom face of the active semiconductor layer 133. The SOI structure is prepared in parallel, and then attached to the structure shown in FIG. 1E by direct whole plate bonding of the bottom face of layer 135 to the top face of layer 121. In this example, the SOI structure extends continuously over the entire top surface of the structure.

FIG. 1G illustrates the structure obtained at the end of the subsequent steps of removing the support substrate 131 and insulating layer 132, then forming electronic components 140, e.g. MOS transistors, in and on the semiconductor layer 133. Forming components 140 may comprise one or more steps of locally implanting doping elements in the semiconductor layer 133. Forming components 140 may further comprise steps of depositing and etching a gate insulator layer and one or more MOS transistor gate conductive layers (not detailed in the figures).

By way of example, the semiconductor layer 133 can be etched through its entire thickness around the components 140, so as to laterally isolate the components 140 from one another. In the example shown, after the components 140 have been formed, an insulating passivation layer 143, e.g. made of silicon oxide, is deposited over the entire top surface of the device, for example over a thickness greater than that of the components 140. A step of planarizing the top face of the insulating layer 143 can further be implemented. The components 140 define an electronic circuit for controlling the sensor, for example a CMOS-type (Complementary Metal Oxide Semiconductor) circuit. The method for producing components 140 will not be described in further detail, as such a method for producing electronic components in so-called 3D sequential technology is within the capabilities of those skilled in the art from the indications of the present description.

FIG. 1H illustrates the structure obtained after subsequent step of forming contact vias, starting from the top face of the structure shown in FIG. 1G. During this step, conductive contact vias are formed on the various components of the sensor, and in particular on the contact regions required for operation of the visible VP and infrared IRP pixels, and possibly on conductive regions of insulation trenches 105 (in the case where these trenches are polarized capacitive insulation trenches). In the example shown, an insulated conductive via 145a extending vertically through layers 143, 135, 121, 119, 117, 111, 115, and 107 is individually in contact with the charge transfer gate TG of each visible pixel VP of the sensor. The sense node SN of each visible pixel VP of the sensor is also connected by a vertical via (not visible in the figure). In addition, an insulated conductive via 145b extending vertically through layers 143, 135, 121, 119, and 117 is individually in contact with an active area of a photosensitive detector of each infrared pixel IRP of the sensor. Further, for each electronic component 140, one or more conductive vias 145c extending vertically through insulating layer 143 come into contact with contact regions of the electronic component, for example gate, drain and/or source regions in the case of MOS transistors.

By way of example, a common contact for all the photosensitive diodes of the infrared pixels IRP of the device can be made at the periphery of the device. By way of example, the common contact couples electronic components of the device to a doped layer (not detailed in the figure) of the active layer 111.

According to an alternative not shown, an individual cathode contact via can be provided for each infrared detection pixel IRP of the device.

The contact on the capacitive isolation trenches 105 can be an individual contact located at each pixel, or a collective contact, taken, for example, at the periphery of the pixel matrix.

FIG. 1I illustrates the structure obtained at the end of subsequent steps of forming an interconnect stack 150 on, and in contact with, the top face of the structure shown in FIG. 1H. The interconnection stack 150 comprises alternating insulating and conducting levels defining interconnection and routing tracks and vias for the various components of the sensor.

FIG. 1J illustrates an optional step for transferring and attaching a second electronic control circuit, for example a CMOS circuit, to and in contact with the top face of the structure shown in FIG. 1I.

For example, the second electronic control circuit is similar to the first electronic control circuit. In the example shown, the second electronic circuit is formed from an SOI structure including a substrate 161 coated with an insulating layer 162, itself coated with a semiconductor layer 163 in and on which components 165, for example MOS transistors, are formed. The second electronic device further comprises, on the side of the semiconductor layer opposite the substrate 161, an interconnection stack 167 having a connection face (bottom face in the orientation shown in FIG. 1J) symmetrical to the connection face (top face in the orientation shown in FIG. 1J) of the interconnection stack 150 of the first electronic circuit.

The second electronic circuit is attached and electrically connected to the first electronic device, for example by direct bonding of the bottom face of the interconnection stack 167 to the top face of the stack 150. The bonding may be a hybrid direct bonding of the copper/oxide type.

Alternatively, rather than using an SOI structure, the second electronic control circuit is made from a less expensive bulk semiconductor substrate.

FIG. 1K illustrates the structure obtained at the end of a step of removing the support substrate 103 from the SOI structure used to form the visible detection structure (FIG. 1A), and then forming optical elements, for example filtering and/or focusing elements, on the light-exposure face side of the sensor, i.e. its top face in the orientation shown in FIG. 1K (one should note that the orientation shown in FIG. 1K is reversed with respect to the orientation shown in FIG. 1J).

In this example, a color filter 181 is formed above each visible pixel VP, adapted to let pass only part of the visible spectrum. By way of example, separate visible pixels VP may be surmounted by separate color filters 181. For example, first visible pixels VP are surmounted by a filter 181 adapted to let pass mainly green light, second visible pixels VP are surmounted by a filter 181 adapted to let pass mainly red light, and third visible pixels VP are surmounted by a filter 181 adapted to let pass mainly blue light. The color filters are designed to let pass infrared light intended to be detected by the infrared pixels IRP. For example, the color filters are made of colored resin.

In this example, a microlens is also formed above each visible pixel VP, adapted to focus incident light into a photosensitive zone of the underlying pixel VP.

Should the step of transferring a second electronic control circuit (FIG. 1J) be omitted, this step can be replaced by a step of attaching a substrate serving as a support handle to the top face of the interconnection stack 150 (in the orientation shown in FIG. 1J).

Alternatively, one should note that the initial SOI structure 103-102-101 can be replaced by a solid semiconductor substrate, e.g. made of silicon. A step of thinning the substrate is from its top face (in the orientation shown in FIG. 1K) is then provided before the steps of depositing the optical elements.

According to one aspect of the described embodiments, the active infrared detection layer 111, the lower reflective layer 119, and the upper interface layer constituted by the stack of layers 107 and 115, define a resonant cavity for the infrared radiation intended to be detected by the sensor.

To this end, the thickness of the active layer 111 and the thickness of the top interface layer 107-115 are selected to maximize the absorption of the radiation of interest in the active layer 111.

Unexpectedly, the inventors have found that it is possible to obtain a very good resonant cavity even when the upper interface layer between the active infrared detection layer 111 and the active visible detection layer 101 made of silicon does not include a reflector. By reflector we here mean a layer or stack of layers having, at the infrared wavelength in question, a reflection coefficient higher than 80%, e.g. higher than 50%, e.g. higher than 20%.

Thicknesses can be selected using standard photonic simulation tools. By way of example, the thickness of the active layer 111 is set to a desired value, preferably less than 1 μm, for example between 200 and 500 μm, then the thickness parameter of the upper oxide layer 107-115 is varied until an absorption peak is obtained.

In practice, the inventors have found that such a resonant cavity makes it possible to achieve an absorption of the infrared radiation of interest higher than 80%, for example of the order of 90% or more, in the active layer 111.

The thickness of the oxide layer 107-115 (sum of the thicknesses of layers 107 and 115) is for example between 10 nm and 800 nm, for example between 100 and 500 nm.

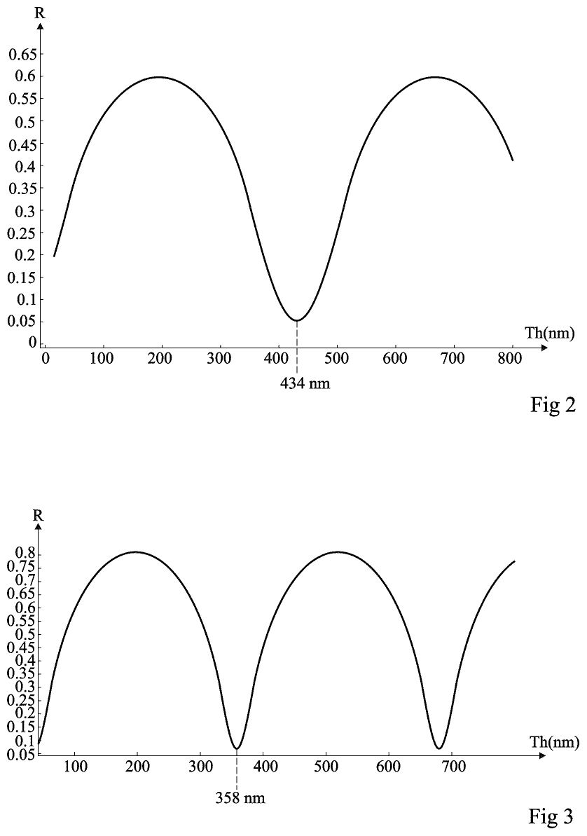

FIG. 2 is a diagram illustrating the evolution of the reflection R of the device, i.e. the proportion of incident radiation not absorbed and not transmitted (it being understood that, in practice, transmission is virtually zero, for example less than 10% or even less than 5%) by the stack comprising the resonant cavity (y-axis, without unit—between 0 and 1), as a function of the thickness Th of the silicon oxide interface layer 107-115 separating the visible detection active layer 101 from the photosensitive detection active layer 111 (x-axis, in nm).

The diagram shown in FIG. 2 is plotted for a sensor in which the active infrared detection layer 111 is a germanium layer 350 nm thick, and for an infrared wavelength of interest of 1.4 μm. It can be seen that the stack has an absorption peak (corresponding to a reflection minimum), of the order of 95%, for a silicon oxide interface layer 107-115 thickness of the order of 434 nm. Since transmission through the entire stack is very close to zero, and absorption in the top silicon layer (visible sensor) is also very close to zero for the wavelength in question, absorption is essentially achieved in the resonant cavity.

The embodiments described are not limited to the particular example of an active infrared detection layer 111 made of germanium. The layer 111 can be made of any other semiconductor material suitable for converting infrared radiation into electrical charges, e.g. silicon.

FIG. 3 is a diagram illustrating the evolution of the reflection coefficient R of the resonant cavity (y-axis), as a function of the thickness Th of the interface layer 107-115, in the case where the active infrared detection layer 111 is made of silicon.

The diagram shown in FIG. 3 is plotted for an active infrared detection layer 111 with a thickness of 200 nm, and for an infrared wavelength of interest of 940 nm. It can be seen that the resonant cavity shows an absorption peak (corresponding to a reflection minimum), of the order of 90%, for a silicon oxide interface layer 107-115 thickness of the order of 358 nm. Here again, since transmission through the entire stack is very close to zero, and absorption in the top silicon layer (visible sensor) is relatively low, e.g. around 20%, most of the absorption takes place in the resonant cavity.

One advantage of the proposed sensor is that it comprises a visible detection stage and an infrared detection stage superimposed on each other, with the infrared detection stage having very good quantum efficiency, without compromising on the resolution and pixel size of the visible detection stage.

A further advantage is that, thanks to the use of a resonant cavity, the active infrared detection layer 111 is relatively thin, e.g. thinner than the wavelength of the infrared radiation to be detected, e.g. less than 1 μm. Further, the distance between the visible detection active region 101 and the infrared detection active region 111 (i.e. the thickness of the interface layer separating layer 101 from layer 111) is relatively small, for example between 10 and 800 nm, for example between 100 and 500 nm. As a result, the contact conductive vias passing through layer 111 can have relatively small lateral dimensions. It allows the photon collection surface in infrared pixels IRP to be increased. The relatively low thickness of the detection layer 111 further allows the dark current in the infrared sensor pixels to be reduced. The relatively low thickness of the detection layer 111 also allows the transit time of charge carriers in the detection layer to be reduced, which improves the response time of infrared detectors. Further, the relatively low thickness of the layer 111 allows the cost of manufacturing the sensor to be reduced.

The described embodiments are not limited to the above-mentioned examples of materials (germanium and silicon) for performing the infrared detection active layer 111. More generally, any semiconductor material having an absorption in the infrared range of interest can be used, for example:
Group IV semiconductors, such as silicon (Si), germanium (Ge), or a germanium-tin alloy (GeSn), or an alloy comprising one or more of these materials;
Group III-V semiconductors, such as an indium-gallium-arsenic (InGaAs) alloy;
materials based on quantum dots, e.g. colloidal, for example based on lead sulfide (PbS), lead selenide (PbSe), indium antimonide (InSb), or indium arsenide antimonide (InAsSb); or
organic semiconductor materials or perovskites.

Preferably, the active infrared detection layer 111 is inorganic, the reflective layer 119 is non-metallic, and the interface layer 107-115 separating the active visible detection layer 101 from the active infrared detection layer 111 is non-metallic. This allows the structure to withstand a relatively high thermal budget when producing the transistors 140 of the first control circuit (FIG. 1G). In particular, this allows producing MOS transistors with good electrical performance.

Alternatively, the reflective layer 119 and/or the interface layer between the visible detection active layer 101 and the infrared detection active layer 111 contain metal. In this case, the transistors 140 of the first control circuit (FIG. 1G) can be produced with a limited thermal budget, for example by means of a so-called low-temperature method, comprising only steps carried out at temperatures below 500° C. By way of example, reflective layer 119 comprises aluminum, copper, or titanium. By way of example, in the step shown in FIG. 1F, the direct dielectric-dielectric bonding of the SOI stack to the structure shown in FIG. 1F can be replaced by direct whole-plate metal-to-metal bonding, in which case the reflective layer 119 is formed of the stack of the two metal bonding layers. By way of example, the top interface layer between the active layers 101 and 111 comprises titanium.

Alternatively, reflective layer 119 can be a Bragg mirror consisting of alternating semiconductor layers or dielectric layers with different refractive indices, for example alternating silicon (Si) layers and silicon oxide (SiO₂) or silicon nitride (SiN) layers, or alternating layers of silicon oxide (SiO₂) and layers of silicon nitride (SiN), or alternating layers of silicon oxide (SiO₂) and layers of hafnium oxide (HfO₂), or any other suitable pair of materials depending on the targeted infrared wavelength.

Should the active infrared detection layer 111 be made of a III-V semiconductor material, the reflective layer 119 can be a Bragg mirror consisting of alternating epitaxial layers of I-V materials, for example alternating layers of aluminum arsenide (AlAs) and gallium arsenide (GaAs).

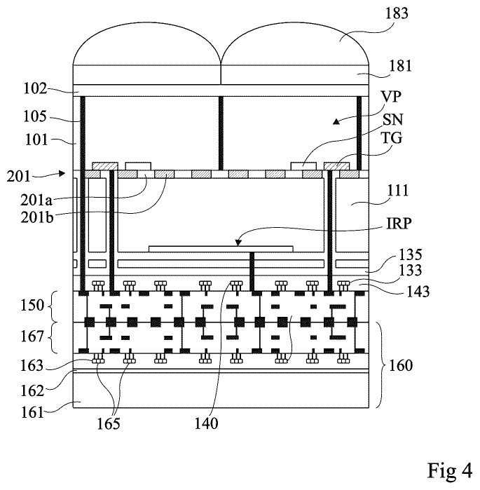

FIG. 4 is a cross-sectional view illustrating a variant of a visible and infrared image sensor according to one embodiment.

The sensor shown in FIG. 4 differs from the sensor shown in FIG. 1K mainly in that, in the sensor shown in FIG. 4, the interface layer 107-115 between the visible detection active layer 101 and the infrared detection active layer 111 is replaced by a structured interface layer 201. The structured interface layer 201 comprises alternating, for example periodic, first regions 201a made of a dielectric material, and second regions 201b made of a semiconductor or metallic material.

In the example shown, the first regions 201a and the second regions 201b each have a top face in contact with the bottom face of the visible detection active layer 101 and a bottom face in contact with the top face of the infrared detection active layer 111.

For example, the first regions are made of silicon oxide. For example, the second regions are made of germanium or a metal, e.g. titanium.

The repetition period of the first regions 201a and second regions 201b is preferably less, in both row and column directions, than the inter-pixel pitch of the visible pixel VP matrix of the sensor. By way of example, the repetition period of the first and second regions 201a and 201b is at least two times smaller, and preferably at least four times smaller, than the repetition pitch of the visible pixels VP of the sensor. By way of example, the lateral dimensions of the first regions 201a and second regions 201b are less than 1 μm, preferably less than 500 nm.

The lateral dimensions as well as the pitch or repetition period of the first and second regions 201a, 201b of the layer 21 are set, for example by means of optical simulation tools, so as to obtain a compromise between the absorption of infrared radiation in the active layer 111, which should be as high as possible, the absorption of infrared radiation in the active layer 101, which should be as low as possible, and the absorption of visible radiation in the active layer 101, which should be as high as possible.

To this end, regions 201a and 201b may have different lateral dimensions and a different repetition pitch with respect to visible pixels VP of different colors.

As an alternative, not shown, the interface layer between the active layers 101 and 111 comprises a structured layer identical or similar to the layer 201 described in relation to FIG. 4, and a non-metallic layer, for example a homogeneous dielectric layer, superimposed on the structured layer. By way of example, the interface layer may comprise:
a homogeneous dielectric layer in contact, via its bottom face, with the top face of the structured layer 201 and in contact, via its top face, with the lower face of the visible detection active layer 101; and/or
a homogeneous dielectric layer being in contact, via its top face, with the bottom face of the structured layer 201 and being in contact, via its bottom face, with the top face of the infrared detection active layer 111.

Various embodiments and variants have been described. Those skilled in the art will understand that certain features of these embodiments can be combined and other variants will readily occur to those skilled in the art. In particular, the embodiments described are not limited to the examples of materials, dimensions, and wavelength ranges mentioned in the present description.

Furthermore, examples have been described above in which the active infrared detection layer 111 extends continuously and with a substantially uniform thickness over substantially the entire surface of the sensor.

Alternatively, the sensor comprises isolation trenches extending vertically through at least part of the thickness of the active layer 111 and delimiting laterally in the active layer 111 islands or mesas forming the infrared detection pixels IRP of the sensor. The isolation trenches can extend through the whole thickness of the active layer 111, thus delimiting separate islands of active layer 111, corresponding respectively to the different infrared detection pixels IRP of the sensor. Alternatively, the isolation trenches extend through only part of the thickness of the active layer 111, and delimit active layer 111 mesas corresponding respectively to the different infrared detection pixels IRP of the sensor.

For example, when viewed from above, each pixel IRP is completely surrounded and separated from the other pixels by isolation trenches. By way of example, when viewed from above, the isolation trenches form a gate separating the pixels IRP of the device laterally from one another.

In the example described in relation to FIGS. 1A to 1K, the isolation trenches are formed, for example, by locally etching the active layer 111 after the transfer step shown in FIG. 1C.

A passivation layer can then be deposited on the sidewalls of the trenches, and then the trenches can be filled with a dielectric filler material, prior implementing subsequent steps and in particular prior to the steps of forming the one or more integrated circuits for controlling the sensor.

1. A visible and infrared image sensor, comprising:
a first active layer for detecting visible radiation, in which a plurality of visible detection pixels are defined; and
superimposed on the first active layer, a second active layer for detecting infrared radiation, in which a plurality of infrared detection pixels are defined,
wherein the second active layer defines a vertical resonant cavity for said infrared radiation,
the sensor further comprising, on the side of the face of the second active layer opposite the first active layer, a control integrated circuit superimposed on the first and second active layers,
wherein the first active layer and the second active layer are separated by an interface layer, the interface layer in contact, via a first face, with the first active layer and, via a second face, with the second active layer,
wherein:
a) the interface layer is non-metallic, or
b) the interface layer comprises a structured layer comprising alternating first regions made of a dielectric material and second regions made of a semiconductor or metallic material.

2. The sensor according to claim 1, wherein the interface layer has a thickness of between 10 and 800 nm.

3. The sensor according to claim 1 in its alternative a), wherein the interface layer is made of silicon oxide.

4. The sensor according to claim 1 in its alternative b), wherein the interface layer further comprises a homogeneous layer, for example dielectric, superimposed on the structured layer.

5. The sensor according to claim 1, wherein the first active layer is made of silicon.

6. The sensor according to claim 1, wherein the second active layer is made of an inorganic semiconductor material.

7. The sensor according to claim 1, wherein the second active layer is made of germanium or silicon.

8. The sensor according to claim 1, comprising a reflective layer, for example of doped semiconductor material, on the side of the face of the second active layer opposite the first active layer.

9. The sensor according to claim 1, wherein said infrared radiation is radiation with a wavelength between 900 nm and 2 μm.

10. The sensor according to claim 1, comprising isolation trenches extending vertically through at least part of the thickness of the second active layer and laterally delimiting islands or mesas in the second active layer forming the infrared detection pixels.

11. A method for manufacturing a visible and infrared image sensor, comprising the following steps:
a) providing a first active layer for detecting visible radiation, in which a plurality of visible detection pixels are defined;
b) attaching, by direct bonding, to the first active layer, a second active layer for detecting infrared radiation; and
c) defining a plurality of infrared detection pixels in the second active layer,
wherein the second active layer defines a vertical resonant cavity for said infrared radiation, the method further comprising, after step c), a step of transferring and attaching a silicon layer, by direct bonding, onto the second active layer, and then forming MOS transistors in said silicon layer,
wherein the first active layer and the second active layer are separated by an interface layer, the interface layer being in contact, via a first face, with the first active layer and, via a second face, with the second active layer,
wherein:
a) the interface layer is non-metallic, or
b) the interface layer comprises a structured layer comprising alternating first regions of a dielectric material and second regions of a semiconductor or metallic material.
